(19) United States
(12) Patent Application Publication
(10) Pub. No.: US 2004/0091749 A1
(43) Pub. Date: May 13, 2004

(54) Method of making coated cemented carbide cutting tools

(76) Inventor: Marian Mikus, Skarholmen (SE)

Correspondence Address: BURNS DOANE SWECKER & MATHIS L L P, POST OFFICE BOX 1404, ALEXANDRIA, VA, 22313-1404, US

(21) Appl. No.: 10/432,436

(22) PCT Filed: Nov. 23, 2001
(86) PCT No.: PCT/SE01/02600

(30) Foreign Application Priority Data
Nov. 23, 2000 (SE) 0004290-3

(51) Int. Cl. C23C 16/26; B32B 18/00

(52) U.S. Cl. 428/698; 427/249.1

(57) ABSTRACT

According to the present invention there is now provided a body cemented carbide provided with at least one wear resistant layer, which body contains a toughness increasing surface zone. Increase in toughness is obtained due to the presence of a surface zone having increased WC grain size and/or increased Co content. The invention is most suitable for WC−Co cemented carbides.

The present invention relates to coated cemented carbide cutting tools with improved properties obtained by a heat treatment of the cemented carbide before the application of a wear resistant coating. The invention is in particular applicable to WC+Co based cemented carbide but can also be applied to cemented carbide consisting of WC+Co+gamma phase (gamma phase is a common name for solid solution carbide, mainly comprising besides W also Ti, Ta and Nb).

A common method for achieving an improvement in toughness of coated cemented carbide cutting tool inserts is by various types of gradient sintering methods in which Co enriched surface zones are formed. Two major methods are used.

In one method an addition of nitrogen in the form of TiN, or Ti(C,N) to WC−Co−gamma phase grades is used, which during sintering develop a Co-enriched surface zone free from gamma phase with thickness of up to 30 μm.

In the other method, a controlled slow rate of cooling down from the sintering temperature is used, whereby a Co-enriched surface zone having Co in the form of stratified structure is formed. This is achieved in WC−Co−gamma phase or WC−Co based cemented carbide having carbon content over the carbon saturation point and thus containing free graphite.

U.S. Pat. No. 4,830,930 discloses a surface refined sintered alloy body which comprises a hard phase and a binder phase. The concentration of the binder phase in the surface layer is highest at the outermost surface thereof and approaches the concentration of the inner portion, the concentration of the binder phase decreasing from the outermost surface to a point at least 5 μm from the surface. The method for making the same includes applying a decarburization treatment at the surface of the sintered alloy at temperatures within the solid-liquid co-existing region of the binder phase after sintering or in the process of sintering.

U.S. Pat. No. 4,830,886 discloses a process for forming a coated cemented carbide cutting insert by chemically vapour depositing a layer of titanium carbide under suitable conditions to form a titanium carbide coated insert with eta phase in the cemented carbide substrate adjacent to said titanium carbide coating. Subsequently said titanium carbide surface is contacted with a carburizing gas for a sufficient time and at a sufficient temperature to convert substantially all of said eta phase to elemental cobalt and tungsten carbide. U.S. Pat. No. 5,665,431 is similar but relates to a titanium carbonitride coating.

WO 99/31292 discloses a body of cemented carbide provided with at least one wear resistant layer, which body contains a zone in the cemented carbide and adjacent to the applied layer, containing triangular WC platelets with a specific orientation.

WO 98/35071 relates to a method comprising the steps of: a) removing carbon from a surface layer of a cemented carbide substrate at a temperature in the region of about 900° C. to about 1400° C. and in an oxygen-containing atmosphere b) reintroducing carbon into the surface layer of the substrate at a substrate temperature in the region of about 900° C. to about 1400° C. in a carbon-containing atmosphere and c) coating the substrate with a hard material.

WO 00/31314 describes coated tools and method of manufacture. The process includes formation of an eta phase containing surface zone, conversion treatment in at least partial vacuum during which a surface is obtained with microroughness greater than 12 micro inches and comprising eta phase and fibrous tungsten carbide grains.

EP-A-0 560 212 describes coated cemented carbide with a Co-enriched surface zone used for cutting tool and having improved resistance for chipping without sacrificing to wear. Zr and Hf comprising phases are present within the cemented carbide. The Co enriched surface zone comprises WC grains with increased grain size compared to the inner parts of the cemented carbide.

It has now surprisingly been found that cemented carbide inserts, first heat-treated in a decarburizing atmosphere at temperatures within the solid region of the binder phase to form an eta phase containing surface zone, then heat-treated in neutral gas atmosphere, such as Ar, or in vacuum at temperatures within the liquid region of the binder phase whereby the eta phase in the surface zone is completely retransformed to WC+Co with or without further additional heat treating steps, exhibit improved properties compared to prior art tools with regard to improved tool life due to increased toughness.

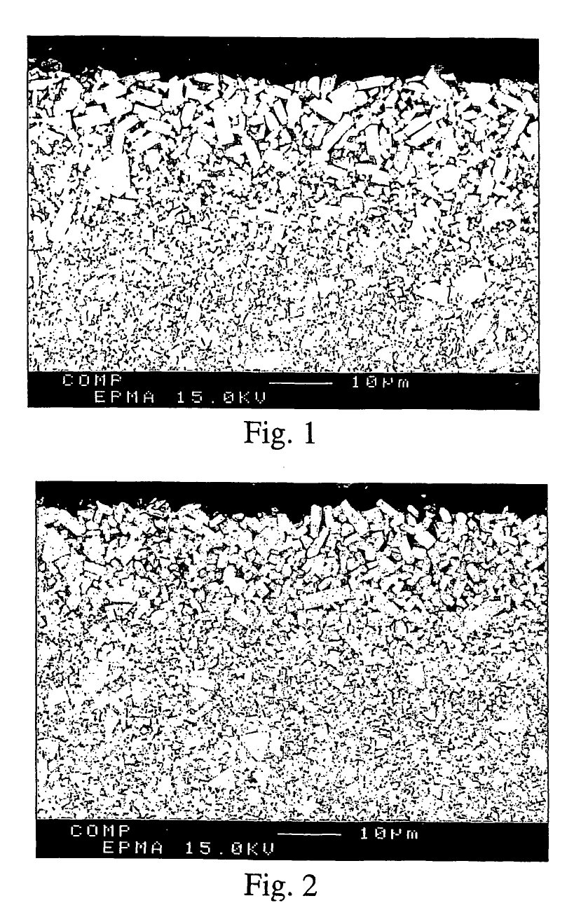

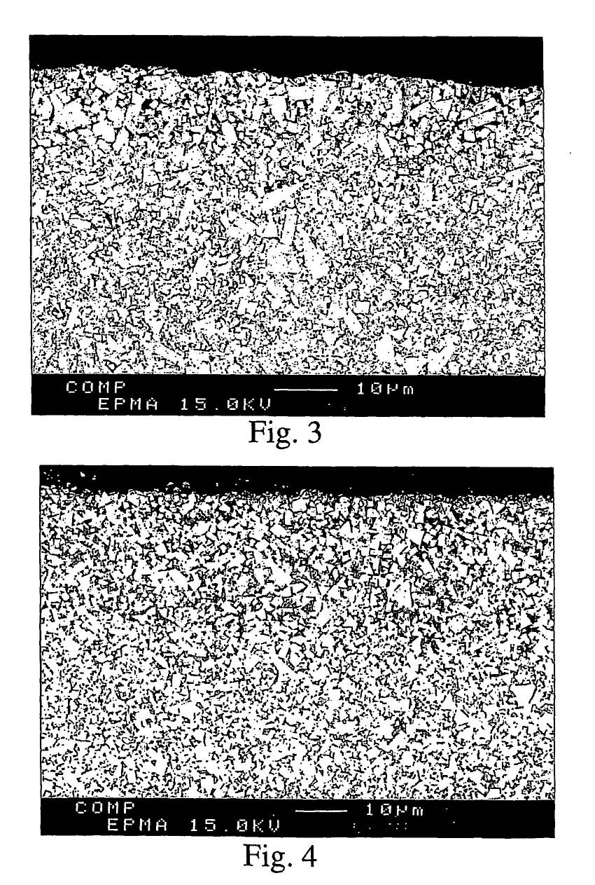

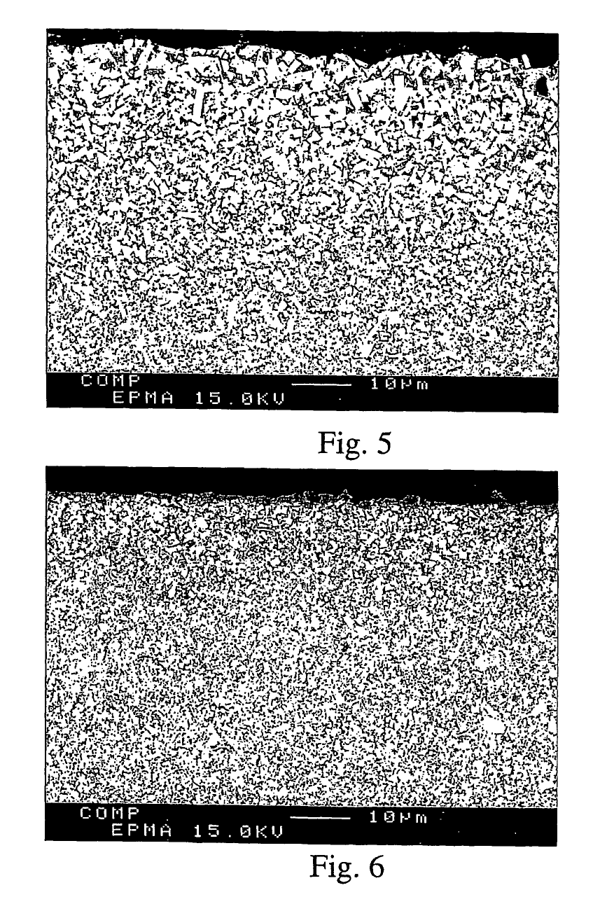

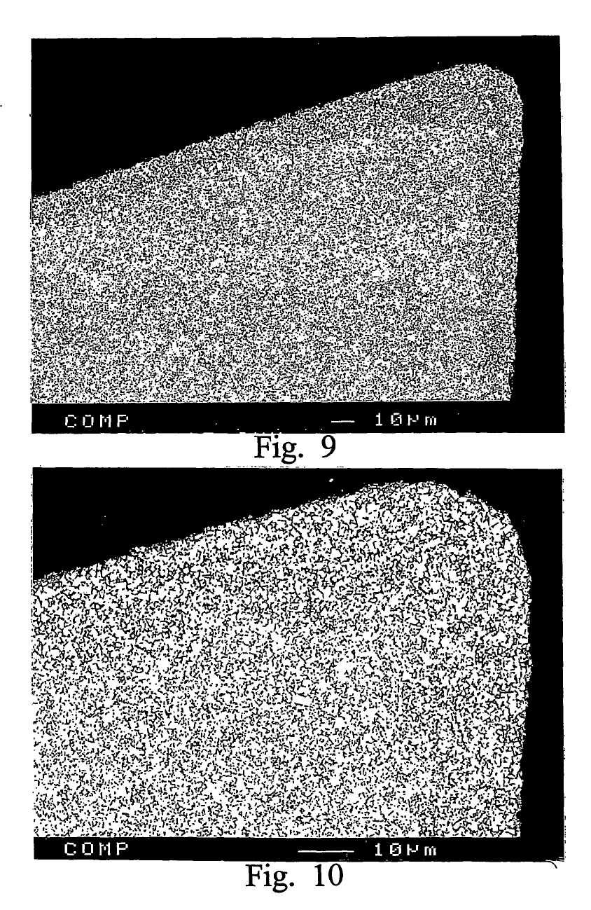

FIGS. 1 to 6 and 9 and 10 show scanning electron micrographs of the surface zone after decarburizing in a decarburizing atmosphere+heat treating in a neutral gas atmosphere.

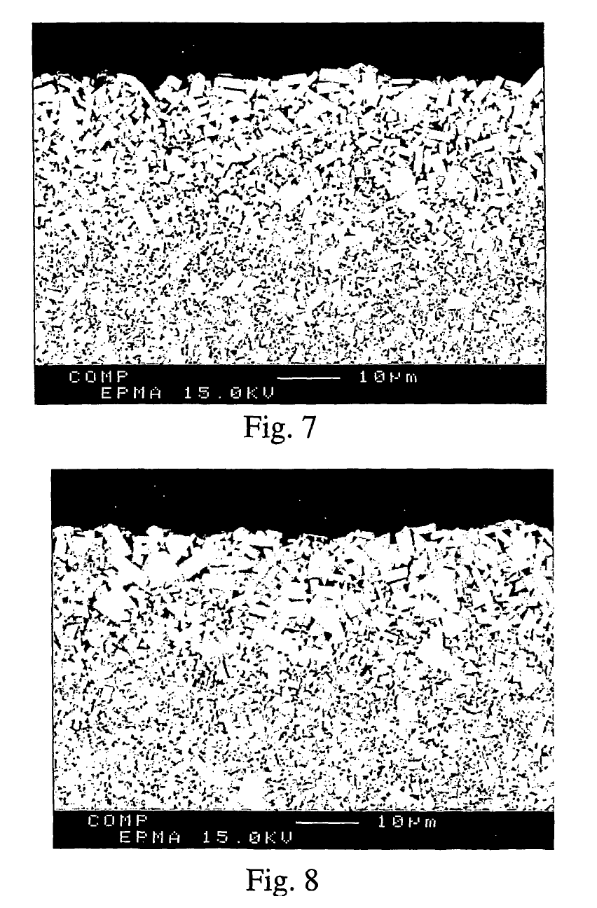

FIG. 7 shows a scanning electron micrograph of the surface zone after decarburizing in a decarburizing atmosphere+heat treating in a neutral gas atmosphere+an additional heat treating in a carburizing atmosphere.

FIG. 8 shows a scanning electron micrograph of the surface zone after decarburizing in a decarburizing atmosphere+heat treating in a neutral gas atmosphere+an additional heat treating in a carburizing atmosphere+another additional heat treating in a neutral gas atmosphere+further another additional heat treating in a carburizing atmosphere.

The images are from the cross-sections of cutting tool inserts.

According to the method of the present invention cemented carbide bodies are first decarburized by heating them to a temperature between 900 and 1290° C. (heat treating step No 1), preferably between 1000 and 1250° C., in a decarburizing atmosphere such as H₂+H₂O, or H₂+CO₂. The time for the treatment is between 1 and 10 h. The degree of decarburization depends on temperature, time and oxygen content in the decarburizing gas, and also on the furnace type.

The decarburization treatment results in a <100 μm thick surface zone containing essentially eta phase, or W+Co₇W₆, or W+eta phase, or eta phase+WC. (Eta phase is a common name for low carbon containing carbides usually comprising W−Co−C in proportions M₆C or M₁₂C, M=W and Co such as M₁₂C=Co₆W₆C and M₆C=CO₃W₃C, W₄CO₂C). In WC−Co−gamma phase grades also the gamma phase will be present within the decarburized zone besides the eta phase. Other phases which may be found in the surface zone are oxides of the elements present in the cemented carbide bodies. In WC−Co grades WO₃ and CoWO₄ phases may also be present in the surface zone.

Decarburization at temperatures between 950 and 1050° C. gives more even thickness of the decarburized zones along the entire surface of the treated bodies whereas decarburization at temperatures between 1200 and 1290° C. gives thicker decarburized zones at the edges and corners than at the plane faces of the bodies.

After the decarburization step (-heat treating step No 1) the bodies are heat-treated in a neutral gas atmosphere or vacuum in heat treating step No 2, to retransform the eta phase or other phases formed during decarburization to a Co enriched WC+Co comprising surface zone. This heat treatment is performed at a temperature between 1350 and 1450° C. for 10 min to 10 h, preferably for 30 min to 3 h. The selection of suitable temperature and holding time is influenced by the carbon content and degree of decarburization of the heat treated bodies. Bodies subjected to stronger decarburization need longer holding time and/or higher heat treating temperature than bodies subjected to weak decarburization. For bodies with high carbon content close to the saturation point the heat treating temperature should be selected to within the range of 1350-1400° C. and for bodies with low carbon content close to formation of eta phase the temperature should be within the range 1400-1450° C. The heat treating step No 2 can be performed at one temperature with one holding time, or at more than one temperature and more than one holding time. For example, one part of this heat treatment can be performed at lower temperature such as 1375° C. with holding time 1.5 h and another part at higher temperature such as 1450° C. with a holding time of 3 h.

During heat treating step No 2 the shape of the WC grains can be unchanged or changed to platelet form. Depending on the degree of decarburization and the selection of the heat treating temperature in step No 2 there will form WC platelets with or without specific orientation. The formation of the WC platelets is easier in cemented carbide bodies without grain growth inhibitors.

For intermediate to low degree of decarburization and low temperature in heat treating step No 2, a surface monolayer of WC platelets will form oriented perpendicularly to the surface of the body. At intermediate to high temperature during heat treating step No 2 there will form WC platelets embedded in the surface zone without specific orientation. In certain embodiments treated with high degree of decarburization and high heat treating temperature in heat treating step No 2, there will form within the surface zone of certain embodiments WC platelets with orientation parallel with the surface of the cemented carbide body. Parallel orientation of the WC platelets is easier formed in bodies with high carbon contents close to saturation point.

If the temperature in heat treating step No 2 is selected between 1250 and 1340° C., and the bodies subjected to low or intermediate degree of decarburization, there will be formed in certain embodiments a surface comprising WC platelets with increased grain size compared to the nominal WC grain size. The WC platelets will have a specific orientation with the major part of the platelets being oriented perpendicularly to the surface of the body. The major part of the WC grains is present in the form of a surface monolayer of WC platelets. Depending on the selection of the holding time and temperature the WC platelets can be surrounded by eta phase at short holding time <0.1-0.5 h or by high Co contents (Co-enrichment) at intermediate holding time 0.5-2 h, or by very low Co-contents (Co-depletion) at long holding time 2-4 h.

If the formation of the surface with a surface monolayer of WC grains with specific WC-platelets orientation is not wanted, the heat treatment should be performed in neutral gas atmosphere or vacuum at temperatures higher than 1350° C. (heat treating step No 2), with holding time selected so that no eta phase is present after the heat treatment. Such surface zones will in certain embodiments comprise WC grains with increased WC grain size with or without platelet form. The WC grains with increased grain size will be present within the whole surface zone and not only at the surface.

During heat treatment step No 2, the eta phase is transformed to a WC+Co surface zone with or without increased WC grain size and with Co enrichment, using carbon from the inner parts of cemented carbide bodies. The maximum Co content within the surface zone is obtained just after completed transformation of the eta phase to WC+Co. Prolonged holding time and/or increased heat treating temperature after formation of the WC+Co zone enriched in Co, will result within the surface zone of certain embodiments in decreased Co content. In embodiments with surface zones with increased WC grain size the Co content after prolonged heat treating holding time/heat treating step No 2A, and/or additional treatment in increased heat treating temperature/heat treating step No 2B, both steps in neutral atmosphere will result in Co contents approximately the same, or even lower than the nominal Co content. The heat treating step No 2B can be performed at more than one heat treating temperature and more than one holding time.

During holding time after completed transformation of the eta phase to WC+Co in certain embodiments WC grain growth will occur. Limited WC grain growth occurs also within the rest of the cemented carbide body, but due to higher Co content within the surface zone compared to the rest of the body the WC growth will be much faster within the surface zone than in the rest of the body. The selection of holding time and temperature depends on the degree of decarburization. All eta phase within the surface zone is transformed to WC+Co. The surface zone shall be 5-100 μm, preferably 5-30 μm, thick.

The thickness of the surface zone at the cutting tool edges is the same as that at the plane surfaces, or it is <5 times, preferably <2 times, thicker at the cutting edges. No or small difference in thickness is obtained for cemented carbide bodies with weak decarburization at low temperatures or weak to medium decarburization and bodies with increased Co contents more than 8 weight-%. In certain embodiments with thick zones obtained after heavy decarburization it is suitable to remove the surface zone at the clearance side of the cutting tool and thus obtain cutting tools with equal thickness on the rake face. Another possibility to decrease the thickness of the surface zone at the cutting edges is to perform the edge rounding process of the cutting tool after the heat treating process and not before as usual. In that case will be the thickness of the surface zone at the cutting edges between 10% to 90% of the thickness at the plane surface, or in certain embodiments it can be completely removed at the outermost parts of the cutting edge within 10 to 100 μm long distance measured at the cross section of the cutting edge. The difference in thickness of the surface zone at the cutting edges and the plane surfaces is due to larger decarburization of the edges than the plane surfaces obtained due to the decarburizing treatment. In certain embodiments the surface zone is present only at the cutting edges to a distance of 1 mm or preferably up to 0.5 mm from the outermost part of the edge. The surface roughness Rₐ is <10 μm, preferably <5 μm.

The Co-content within the surface zone may be at least 10% higher, or between +10% and −40% of the nominal Co-content. The size and shape of the WC grains may be changed or remain unchanged.

The WC grain size within the surface zone can be increased by at least by 20%, preferably by more than 30%, or be more or less unchanged compared to the nominal WC grain size within the rest of the body. The increase of the WC grain size takes place mainly in WC−Co bodies without grain growth inhibitors. Larger increase is obtained for cemented carbide grades with relatively high carbon content close to the saturation point compared to grades with low carbon contents close to the formation of eta phase. Within the surface zones with increased WC grain size a WC grain size gradient is observed. The grain size increases from the inner parts of the surface zone towards the outer parts of the surface zone. Both types of the surface zones with or without increase in WC grain size and with Co enrichment are suitable in cutting operations with large demands on toughness.

Surface zones with an increase of the WC grain size or with Co enrichment give increased tool life in cutting operation with large demands on toughness and resistance to deformation at elevated temperatures and chipping resistance.

In bodies obtained after the heat treating steps No 1 and 2, resulting in surface zones with increased WC grain size and increased Co content over the nominal level, it is suitable to reduce the Co content within the surface zone to about the same level as the nominal Co level or even somewhat lower than the nominal level. This is obtained by either prolonging the heat treating holding time of step No 2—up to 5 h in neutral atmosphere or vacuum/heat treating step 2A and/or by using additional heat treatment or treatments, at high heat treating temperatures—up to 1450 ° C./heat treating step No 2B, in neutral atmosphere or vacuum.

Another possibility how to reduce or adjust the Co content is to use after step No 2 further additional heat treating steps where at least one of heat treating steps is performed in reducing atmosphere-containing CH₄+H₂ gas mixture. Reduction in the Co content is obtained in further additional heat treating steps (heat treating steps No 2A, 2B, 3, 4 and 5) after heat treating steps No 1 and 2.

The heat treating step No 3 is performed in a carburizing atmosphere such as CH₄+H₂, within the temperature range 1200-1370° C. and the time 0.1-2 h.

The heat treating step No 4 is performed in a neutral gas atmosphere or vacuum at temperatures between 1350 and 1450° C. and holding time between 0.1 and 2 h.

The heat treating step No 5 is performed in a carburizing atmosphere such as CH₄+H₂, within the temperature range 1200-1370° C. and the time 0.1-2 h.

After heat treating steps No 1, 2, 2A, 2B or 1, 2 and 3 the Co content within the surface zone is reduced to within ±20% variation of the nominal Co content.

After heat treating steps No 1, 2, 2A, 2B or 1, 2, 3 and 4 the Co content within surface zone is adjusted to within ±10% variation of the nominal Co content.

After heat treating steps 1, 2, 3, 4 and 5 the Co content within surface zone is reduced to between −20 and −40% of the nominal Co content.

The difference between using heat treating steps No 1+2, 1+2+2A, 1+2+2B and No 1+2+3, No 1+2+3+4, No 1+2+3+4+5 in reducing Co content in surface zone is that the total carbon content of the bodies will be lower after heat treating in neutral atmosphere step No 2A 2B than after using carburizing atmosphere—steps No 3 and 5.

Bodies according to the invention are coated with wear resistant coatings using known coating methods.

The method of the present invention can be applied to WC−Co bodies with or without addition of <3 weight-%, preferably <2.5 weight-% grain growth inhibitors such as Cr, Ti, Ta, Nb and V, with 3-12, preferably 5-12, weight-% binder phase, with average WC grain size of 0.3-3 μm, preferably 0.5-1.7 μm, with a carbon content not exceeding carbon saturation. Preferably no eta phase is present in the bodies prior to the decarburizing treatment. The method of the present invention can also be applied to WC−Co−gamma phase bodies, comprising totally up to 10 weight-% of at least one of following elements Ti, Ta, Nb, Zr, Hf. The binder phase is preferably Co but it can comprise or consist of other elements such as Fe and Ni or mixtures thereof.

In a first preferred embodiment intermediate to strong decarburization is performed at a temperature between 1000 ° C. and 1250° C. (heat treating step No 1), holding time 2-10 h, in H₂+H₂O with dew point between 0° C. and −30° C., or H₂+CO₂ atmosphere containing 10-20% CO₂ followed by a heat treatment performed in a neutral gas atmosphere or vacuum between 1360 and 1410° C. (heat treating step no 2) for 0.5 to 5 h.

As a result of the heat treatments No 1 and 2 it is obtained a surface zone with the WC grains having an average grain size 20% larger, preferably 30% larger, than the average WC grain size within the cemented carbide body. The surface zone is 5-100 μm thick, preferably 10-30 μm thick, with an average Co content at least 10%, preferably 30%, higher than the nominal Co content.

In bodies with surface zones having increased WC grain size there may be present an additional intermediate zone between the surface zone and the inner parts of the body. This intermediate zone has about the same thickness or is up to 200% thicker than the surface zone and comprises WC phase with grain size 10-30% smaller than that within the cemented carbide body. The Co content within this zone may be within 10% variation essentially the same as the nominal Co content outside the surface zone or between 10% and 30% lower than the nominal Co content. An intermediate zone with decreased WC grain size may be present in cemented carbide bodies with Co contents below 8 weight-%, without grain growth inhibitors and subjected to a strong decarburization treatment. This intermediate zone is absent in bodies with grain growth inhibitors and/or Co contents above 8 weight-%.

Within the surface zone the shape of the major part of the WC grains is essentially unchanged or partly changed to platelet form. The WC grain size and the amount of the WC platelets increase within the surface zone towards the surface of the body. Grain growth also takes place in WC−Co bodies containing small amounts of weak grain growth inhibitors. However, no WC grain growth is observed in bodies containing VC.

Cemented carbide according to this embodiment is most suitable in cutting operations with large demands on mechanical toughness in cutting operations using heavy interrupted cuts in steel or cast iron without coolant.

The second preferred embodiment is obtained using bodies from the first preferred embodiment being furthermore heat treated in the three additional heat treating steps No 3, 4 and 5. After heat treating steps No 1, 2 and 3 the Co content within surface zone is adjusted to within 20% variation of the nominal Co content. After heat treating steps No 1, 2, 3 and 4 the Co content within the surface zone is adjusted to within 10% variation of the nominal Co content and after heat treating steps No 1, 2, 3, 4 and 5 the Co content within the surface zone is adjusted to between −20 and −40% of the nominal Co content. The average WC grain size within the surface zone is within 10% variation the same or up to 30% larger as in the first preferred embodiment.

Similar results as obtained after heat treating steps No 3, 4, 5 with respect to Co content and the WC grain size are obtained after prolonged holding time in step No 2/in heat treating step No 2A, at 1350° C.-1450° C., preferably between 1350 and 1400° C., and up to 5 h holding time in neutral atmosphere or vacuum, or by using heat treating step No 2B performed at high heat treating temperature up to 1450° C. and holding time between 1-3 h/in neutral gas atmosphere or vacuum. The heat treating step No 2B can be performed at more than one temperature and more than one holding time. If the treatment is performed at two different temperatures it is suitable that the first heat treating temperature is at least 20° C., preferably more than 50° C., lower than the second heat treating temperature.

Cemented carbide according to this embodiment is most suitable in toughness demanding cutting operations with increased amounts of thermal cycling leading to the creation of thermal cracks and thermally induced flaking, occurring during interrupted cutting of stainless steel with coolant.

The third preferred embodiment is obtained in WC−Co based bodies containing conventional amounts of grain growth inhibitors after weak to intermediate decarburization heat treatment (heat treating step No 1). The decarburizing treatment is performed either at relatively low temperatures such as 950-1000° C., for up to 10 h in a H₂+H₂O atmosphere with a dew point between +15 and +25° C. or at relatively high temperatures such as 1250° C. for 1-2 h and in a H₂+H₂O atmosphere with a dew point between −20 and −30° C. Thin surface zones are obtained after such decarburizing treatment with a thickness of up to 10 μm. The heat treating step in neutral gas atmosphere (heat treating step No 2) such as Ar or vacuum is performed at 1350-1410° C., for 20 min to 3 h. The surface zone has a Co content at least 10%, preferably 30%, higher than the nominal Co content. The average WC grain size is unchanged or up to 20% larger than the average WC grain size within the rest of the cemented carbide body. The thickness of the surface zone is between 5 and 20 μm, preferably 5 and 10 μm.

Cemented carbide according to this embodiment is most suitable in cutting operations with large demands on toughness using cutting tool inserts with relatively small edge radius.

### EXAMPLES 1-11

Cemented carbide cutting tool inserts CNMG120412 made in the conventional way were heat treated according to the invention according to Table 1. Table 2 shows the resulting surface zone. The inserts were further coated and tested in cutting tests against untreated inserts with the same coating with results according to Table 2.

TABLE 1

| EX. | Cemented carbide | Heat treatment - | Heat treatment - | Heat treatment - |
|---|---|---|---|---|
| No | composition | No 1 | No 2 | No 3, 4, 5 |
| 1 | WC + 5.0 w % Co | 1250° C., 4 h, | 1410° C., 1 h, 30 mbar Ar | None |
| | | H₂ + H₂O | | |
| 2 | WC + 5.0 w % Co | 1250° C., 4 h, | 1410° C., 1 h, 30 mbar Ar | 1330° C., 0.5 h, H₂ + CH₄ |
| | | H₂ + H₂O | | |
| 3 | WC + 5.0 w % Co | 1250° C., 4 h, | 1410° C., 1 h, 30 mbar Ar | 1330° C., 0.5 h, H₂ + CH₄ |
| | | H₂ + H₂O | | +1410° C., 0.5 h vac |
| | | | | +1330° C., 0.5 h, H₂ + CH4 |
| 4 | WC + 6.0 w % Co | 1250° C., 2 h, | 1410° C., 1 h, 30 mbar Ar | None |
| | | H₂ + H₂O | | |
| 5 | WC + 6.0 w % Co | 980° C., 10 h, | 1390° C., 1 h, 30 mbar Ar | None |
| | | H₂ + H₂O | | |
| 6 | WC + 9.5 w % Co, | 1250° C., 4 h, | 1410° C., 1 h, 30 mbar Ar | None |
| | 1.2 w % TaC, | H₂ + H₂O | | |
| | 0.3 w % NbC | | | |
| 7 | WC + 10.0 w % Co, | 1030° C., 8 h, | 1410° C., 1 h, 30 mbar Ar | None |
| | 0.5 w % Cr3C2 | H₂ + H₂O | | |
| 8 | WC + 10.0 w % Co, | 1250° C., 6 h, | 1410° C., 2 h, 30 mbar Ar | None |
| | 0.5 w % Cr3C2 | H₂ + H₂O | | |
| 9 | WC + 3.7 w % Co, | 985° C., 5 h, | 1410° C., 1.5 h, vakuum | None |
| | 1.5 w % TaC, | H₂ + H₂O | | |
| | 0.5 w % NbC | | | |
| 10 | WC + 5.0 w % Co | 1250° C., 4 h, | 1410° C., 1 h, 30 mbar, Ar | 1330° C., 0.5 h, H₂ + CH₄ |
| | | H₂ + H₂O | | +1410° C., 0.5 h vac |
| 11 | WC + 5.8 w % Co, | 1250° C., 4 h, | 1380° C., 2.0 h, Ar | None |
| | 3.5 w % TiC, | H₂ + H₂O | | |
| | 2.3 w % TaC | | | |
| | 3.5 w % NbC | | | |

TABLE 2

| | Surface zone-thickness, | Inside c.c.body, | | Increase in |
|---|---|---|---|---|
| | Co-content, WC-grain | WC-grain size | | tool life |
| EXAMPLE No | size + shape | (μm) | coatings: CVD-MTCVD, PVD | over Ref. |
| 1A | 18 μm, 8.0 w % Co, 3.2 μm | 1.5 | 5 μm TiN—TiCN—Ti (C,O) + | 30% |
| | WC, >50% WC-platelets | | 5 μm Al₂O₃ + 0.5 μm TiN | |
| 1B, REF. | 5.0 w % Co, 1,5 μm WC, | 1.5 | 5 μm TiN—TiCN—Ti (C,O) + | |
| | <5% WC-platelets | | 5 μm Al₂O + 0.5 μm TiN | |
| 2A | 18 μm, 5.5 w % Co, 3.3 μm | 1.6 | 5 μm TiN—TiCN—Ti (C,O) + | 40% |
| | WC, >30% WC-platelets | | 5 μm Al₂O₃ + 0.5 μm TiN | |
| 2B, REF. | 5 w % Co, 1,7 μm WC, <5% WC- | 1.7 | 5 μm TiN—TiCN—Ti (C,O) + | |
| | platelets | | 5 μm Al₂O₃ + 0.5 μm TiN | |
| 3A | 18 μm, 4.0 w % Co, 3.6 μm | 1.7 | 5 μm TiN—TiCN—Ti (C,O) + | 50% |
| | WC, >30% WC-platelets | | 5 μm Al₂O₃ + 0.5 μm TiN | |
| 3B, REF. | 5 w % Co, 1,7 μm WC, <5% WC- | 1.7 | 5 μm TiN—TiCN—Ti (C,O) + | |
| | platelets | | 5 μm Al₂O₃ + 0.5 μm TiN | |
| 4A | 15 μm, 9.0 w % Co, 2.2 μm | 1.5 | 3 μm TiN—TiCN—Ti (C,O) + | 45% |
| | WC, 10% WC-platelets, | | 3 μm Al₂O₃ | |
| 4B, REF. | 6 w % Co, 1.5 μm WC, <5% WC- | 1.5 | 3 μm TiN—TiCN—Ti (C,O) + | |
| | platelets | | 3 μm Al₂O₃ | |
| 5A | 10 μm, 9.0 w % Co, 1.7 μm WC, | 1.6 | 3 μm TiN—TiCN—Ti (C,O) + | 30% |
| | <5% WC-platelets | | 5 μm Al₂O₃ | |
| 5B, REF. | 6 w % Co, 1.6 μm WC, <5% WC- | 1.6 | 3 μm TiN—TiCN—Ti (C,O) + | |
| | platelets | | 5 μm Al₂O₃ | |
| 6A | 25 μm, 14.0 w % Co, 2.2 μm | 1.9 | 5 μm TiN—TiCN—Ti (C,O) + | 40% |
| | WC, <5% WC-platelets | | 5 μm Al₂O₃ | |
| 6B, REF. | 9.5 w % Co, 1.9 μm WC, | 1.9 | 5 μm TiN—TiCN—Ti (C,O) + | |
| | <5% WC-platelets | | 5 μm Al₂O₃ | |
| 7A | 14 μm 14.0 w % Co, 1.2 μm | 0.9 | 0.5 μm TiN + 12 × 6 μm TiN, TiAlN | 55% |
| | WC, <5% WC-platelets | | multilayer | |
| 7B, REF. | 10 w % Co, 0.9 μm WC, <5% WC- | 0.9 | 0.5 μm TiN + 12 × 6 μm TiN, TiAlN | |
| | platelets | | multilayer | |
| 8A | 45 μm, 11-15.0 w % Co, 2.0 | 0.9 | 0.5 μm TiN + 6 μm 12 × TiN, TiAlN | 30% |
| | μm WC, 5-20% WC-platelets | | multilayer | |
| 8B, REF. | 10 w % Co, 0.9 μm WC, | 0.9 | 0.5 μm TiN + 6 μm 12 × TiN, TiAlN | |
| | <5% WC-platelets | | multilayer | |
| 9A | 15 μm, 6.0 w % Co, 1.4 μm WC, | 1.2 | 5 μm TiCN + 0.5 μm TiN | 40% |
| | <5% WC-platelets | | | |
| 9B, REF. | 3.7 w % CO, 1.2 μm | 1.2 | 5 μm TiCN + 0.5 μm TiN | |
| | WC, <5% WC-platelets | | | |
| 10A | 18 μm, 5.0 w % Co, 3.5 μm | 1.7 | 5 μm TiN—TiCN—Ti(C,O) + | 45% |
| | WC, >30% WC-platelets | | 5 μm Al₂O₃ + 0.5 μm TiN | |
| 10B, REF. | 5 w % Co, 1,7 μm WC, <5% WC | 1,7 | 5 μm TiN—TiCN—Ti (C,O) + | |
| | platelets | | 5 μm Al₂O₃ + 0.5 μTiN | |
| 11A | 14 μm, 9.0 w % Co, 2.9 μm | 2.3 | 0.5 μm TiN + 6 μm 12 × TiN, TiAlN | 30% |
| | WC, 20% WC-platelets | | multilayer | |
| 11B, REF. | 5.8 w % Co, 2.3 μm WC, <5% WC- | 2.3 | 0.5 μm TiN + 6 μm 12 × TiN, TiAlN | |
| | platelets | | multilayer | |

1. Method for producing a coated cemented carbide body containing 3-12 weight-% binder phase with a carbon content below saturation point with a 5-100 μm thick surface zone different from the interior of the body whereby the cemented carbide body is decarburized in H₂+H₂O or H₂+CO₂ gas atmosphere at a temperature of 900-1290° C., preferably 1000-1250° C., for 1-10 h to form an eta phase containing surface zone
characterised in that the body is heat treated at a temperature of 1250-1450° C., preferably between 1350 and 1450° C., for 10 min-10 h, preferably 30 in-2 h, in a neutral gas atmosphere or vacuum to completely retransform the eta phase or other phases formed during decarburization to WC+Co phase.

2. Method according to claim 1
characterised in that the cemented carbide body consists of WC−Co.

3. Method according to claim 2
characterised in that the cemented carbide body consists of WC−Co with addition of <3 weight-%, preferably <2.5 weight-% grain growth inhibitors such as Cr, Ti, Ta, Nb and V.

4. Method according to claim 1
characterised in that the cemented carbide body consists of WC−Co−gamma phase comprising totally up to 10 weight-% of at least one of the elements Ti, Ta, Nb, Hf and Zr.

5. Method according to claim 1
characterised in that the cemented carbide body is further heat treated in a carburizing atmosphere, such as CH₄+H₂, in the temperature range 1200-1370 ° C. and the time 0.1-2 h.

6. Method according to claim 5
characterised in that the cemented carbide body is further heat treated in a neutral gas atmosphere or vacuum at temperatures between 1360 and 1450 C. and holding time between 0.1 and 2 h.

7. Method according to claim 6
characterised in that the cemented carbide body is further heat treated in a carburizing atmosphere such as CH₄+H₂, within the temperature range 1200-1370° C. and the time 0.1-2 h.

8. Method according to claim 1
characterised in that the cemented carbide body is heat treated in neutral atmosphere or vacuum using more than one, preferably two, heat treating temperatures and holding times within the temperature range 1360-1450° C. and the time 0.1 to 5 h at each temperature.

9. Method according to claim 8
characterised in that the first heat treating temperature is at least 20° C., preferably more than 50° C., lower than the second heat treating temperature.

10. Coated WC+Co based cemented carbide body, with a carbon content below saturation point, with or without addition of <3,w %, preferably <2.5 w % grain growth inhibitors such as Cr, Ti, Ta, Nb and V, with average WC grain size of 0.3-3 μm, preferably 0.5-1.7 μm, containing 3-12 wt % binder phase, comprising at least one of the elements Co, Ni, Fe, preferably Co, with a 5-100 μm thick surface zone preferably 5-30 μm thick different from the interior of the body, whereby the surface zone is characterised in that:
the WC grains have an average grain size 20% larger, preferably 30% larger than nominal WC grain size, together with average Co content at least 10%, preferably 30% higher than nominal Co content, or:
the WC grains have an average grain size 20% larger, preferably 30% larger than nominal WC grain size, together with Co content within the range of up to 10% larger and down to 40% lower than nominal Co content, or:
the WC grains have an average grain size within the range of ±20% the same as the nominal average WC grain size, together with average Co content at least 10%, preferably 30% higher than nominal Co content.
